(19) United States
(12) Patent Application Publication
(10) Pub. No.: US 2025/0141332 A1
(43) Pub. Date: May 1, 2025

(54) Signal Conversion Apparatus and Control Method

(71) Applicant: LEN TECH Inc., Plano, TX (US)

(72) Inventor: Gonggui Xu, Plano, TX (US)

(21) Appl. No.: 18/383,706

(22) Filed: Oct. 25, 2023

(51) Int. Cl. H02M 1/00; H02M 3/16

(52) U.S. Cl. CPC H02M 1/0009; H02M 3/16

(57) ABSTRACT

An apparatus includes a first differential pair having a first transistor and a second transistor, wherein a gate of the first transistor is configured to receive a first current sensing signal, and a gate of the second transistor is configured to receive a second current sensing signal, a second differential pair having a third transistor and a fourth transistor, wherein a gate of the third transistor is configured to receive a predetermined reference, and a gate of the fourth transistor is connected to a capacitor, and a high gain stage comprising a first leg and a second leg, wherein a first node of the first leg is connected to a drain of the first transistor and a drain of the fourth transistor, and a second node of the second leg is connected to a drain of the second transistor and a drain of the third transistor.

### TECHNICAL FIELD

The present invention relates to a signal conversion apparatus and control method, and, in particular embodiments, to a differential to single-ended signal conversion apparatus connected to outputs of a current sensing apparatus of a power converter.

### BACKGROUND

As technologies further advance, a variety of processors such as Digital Signal Processors (DSPs), Field Programmable Gate Arrays (FPGAs), Central Processing Units (CPUs) and/or the like, have become popular. Each processor operates with a low supply voltage (e.g., sub-1V) and consumes a large amount of current. Meanwhile, the input voltage bus has stayed the same (e.g., 12 V) or increased to a higher level (e.g., 48 V) depending on different applications or design needs.

In a high voltage application where a low output voltage is required, two power stages connected in cascaded are traditionally employed to covert the high input voltage into a suitable low voltage fed into the processor. However, this power architecture increases the system cost and complexity.

In order to reduce the system cost and complexity, a load in the high voltage application may be powered by a power converter. The power converter such as a buck converter includes two power switches connected in series. A first power switch not connected to ground is referred to as a high-side switch. A second power switch connected to ground is referred to as low-side switch. A common node of the high-side switch and the low-side switch is a switching node of the power converter. A low-side gate drive circuit and a high-side gate drive circuit are employed to control the gates of the low-side switch and the high-side switch, respectively.

The low-side switch and the high-side switch may be implemented as metal oxide semiconductor field effect transistors (MOSFET). MOSFETs are voltage-controlled devices. When a gate drive voltage is applied to the gate of a MOSFET, and the gate drive voltage is greater than the turn-on threshold of the MOSFET, a conductive channel is established between the drain and the source of the MOSFET. After the conductive channel has been established, the MOSFET is in an on state in which power flows between the drain and the source of the MOSFET. On the other hand, when the gate drive voltage applied to the gate is less than the turn-on threshold of the MOSFET, the MOSFET is turned off accordingly.

As power consumption has become more important, there may be a need for accurately monitoring and/or controlling the current flowing through the power converter so as to achieve a high-efficiency, safe and reliable operation of the power converter. Current sense devices such as current sense resistors have become the preferred choice for achieving high performance (e.g., accurate current measurement information) because current sense resistors can be connected in series with the inductor of the power converter.

A current sensing apparatus is employed to receive the signals across the current sense resistor, and generate a differential signal proportional to the voltage across the current sense resistor. However, many applications need to convert the differential signal into a single-ended signal for subsequent processing. There are various ways to convert a differential signal into a single-ended signal. For example, a differential to single-ended signal converter may be implemented based on a plurality of operational amplifiers (e.g., two operational amplifiers). This solution has some drawbacks. For example, the silicon area occupied by the plurality of operational amplifiers has become a significant issue, which presents challenges for designers to achieve a cost-effective current sensing solution. It would be desirable to have a simple and reliable differential to single-ended signal conversion apparatus for use in power conversion applications.

### SUMMARY

These and other problems are generally solved or circumvented, and technical advantages are generally achieved, by preferred embodiments of the present disclosure which provide a differential to single-ended signal conversion apparatus connected to outputs of a current sensing apparatus of a power converter.

In accordance with an embodiment, an apparatus comprises a first differential pair having a first transistor and a second transistor, wherein a gate of the first transistor is configured to receive a first current sensing signal, and a gate of the second transistor is configured to receive a second current sensing signal, a second differential pair having a third transistor and a fourth transistor, wherein a gate of the third transistor is configured to receive a predetermined reference, and a gate of the fourth transistor is connected to a capacitor, and a high gain stage comprising a first leg and a second leg, wherein a first node of the first leg is connected to a drain of the first transistor and a drain of the fourth transistor, and a second node of the second leg is connected to a drain of the second transistor and a drain of the third transistor, and wherein the high gain stage is configured to regulate a voltage across the capacitor.

In accordance with another embodiment, a method comprises configuring a first input of a current sensing apparatus to be coupled to a first terminal of a current sense device and a second input of the current sensing apparatus to be coupled to a second terminal of the current sense device, configuring the current sensing apparatus to generate a differential signal formed by a first current sensing signal and a second current sensing signal, and configuring a signal conversion apparatus to convert the differential signal into a single-ended signal through receiving the differential signal, performing a de detection on the differential signal, filtering noise components from the differential signal, and level-shifting the differential signal based on a predetermined reference.

In accordance with yet another embodiment, a power converter comprises a first power switch and a second power switch connected in series between an input voltage bus and ground, an inductor connected between a common node of the first power switch and the second power switch and a first terminal of a current sense device, a capacitor connected between a second terminal of the current sense device and ground, a current sensing apparatus having a first input connected to the first terminal of the current sense device and a second input connected to the second terminal of the current sense device, wherein the current sensing apparatus is configured to generate a differential signal formed by a first current sensing signal and a second current sensing signal, and a signal conversion apparatus configured to convert the differential signal into a single-ended signal across a capacitor through receiving the differential signal, performing a dc detection on the differential signal, filtering noise components from the differential signal, and level-shifting the differential signal based on a predetermined reference.

The foregoing has outlined rather broadly the features and technical advantages of the present disclosure in order that the detailed description of the disclosure that follows may be better understood. Additional features and advantages of the disclosure will be described hereinafter which form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 illustrates a schematic diagram of a power converter and the associated control circuit in accordance with various embodiments of the present disclosure;

FIG. 2 illustrates a schematic diagram of the current sensing apparatus shown in FIG. 1 in accordance with various embodiments of the present disclosure;

FIG. 3 illustrates a block diagram of the signal conversion apparatus shown in FIG. 1 in accordance with various embodiments of the present disclosure;

FIG. 4 illustrates a schematic diagram of the signal conversion apparatus shown in FIG. 3 in accordance with various embodiments of the present disclosure;

FIG. 5 illustrates a block diagram of another signal conversion apparatus in accordance with various embodiments of the present disclosure; and

FIG. 6 illustrates a flow chart of controlling and operating the signal conversion apparatus shown in FIG. 1 in accordance with various embodiments of the present disclosure.

Corresponding numerals and symbols in the different figures generally refer to corresponding parts unless otherwise indicated. The figures are drawn to clearly illustrate the relevant aspects of the various embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that the present disclosure provides many applicable inventive concepts that can be embodied in a wide variety of specific contexts. The specific embodiments discussed are merely illustrative of specific ways to make and use the disclosure, and do not limit the scope of the disclosure.

The present disclosure will be described with respect to preferred embodiments in a specific context, namely a differential to single-ended signal conversion apparatus connected to outputs of a current sensing apparatus of a step-down power converter. The disclosure may also be applied, however, to a variety of power converters. Hereinafter, various embodiments will be explained in detail with reference to the accompanying drawings.

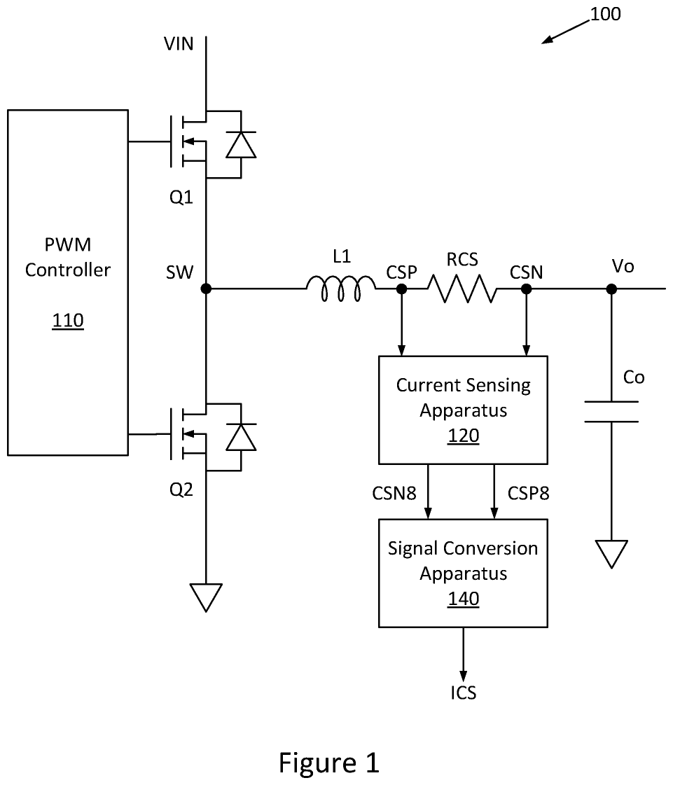

FIG. 1 illustrates a schematic diagram of a power converter and the associated control circuit in accordance with various embodiments of the present disclosure. The power converter 100 is a step-down power converter. The power converter 100 is also known as a buck converter. As shown in FIG. 1, the power converter 100 comprises a first power switch Q1, a second power switch Q2, an inductor L1, a current sense device RCS and an output capacitor Co. In some embodiments, the current sense device RCS is implemented as a current sense resistor coupled between the inductor L1 and the output terminal of the power converter 100.

As shown in FIG. 1, the first power switch Q1 and the second power switch Q2 are connected in series between an input voltage bus VIN and ground. The common node of the first power switch Q1 and the second power switch Q2 is a switching node (SW). The inductor L1 is connected between the common node of the first power switch Q1 and the second power switch Q2, and a first terminal of the current sense device RCS. The output capacitor Co is connected between a second terminal of the current sense device RCS and ground.

The control circuit of the power converter 100 comprises a PWM controller 110, a current sensing apparatus 120 and a signal conversion apparatus 140. The current sensing apparatus 120 is implemented as a wide range current sensing amplifier. As shown in FIG. 1, a first input of the current sensing apparatus 120 is connected to the first terminal of the current sense device RCS. A second input of the current sensing apparatus 120 is connected to the second terminal of the current sense device RCS. Throughout the description, the first terminal of the current sense device RCS is alternatively referred to as a CSP node. The second terminal of the current sense device RCS is alternatively referred to as a CSN node.

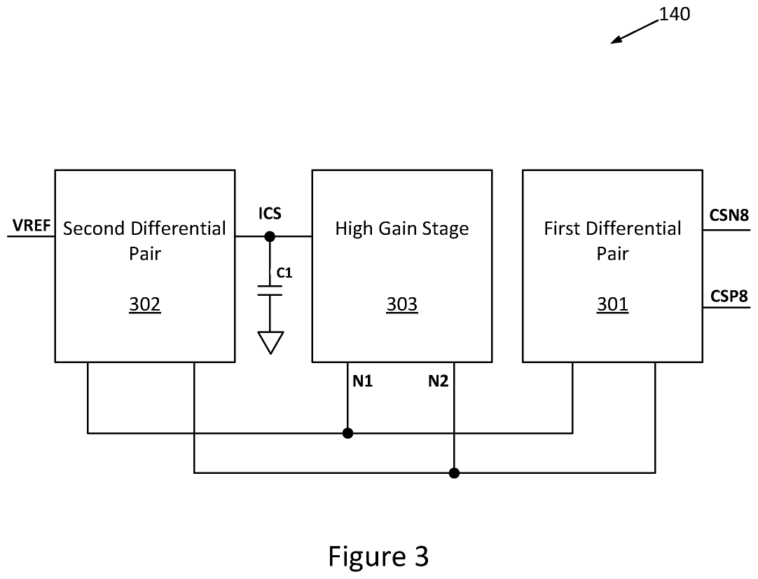

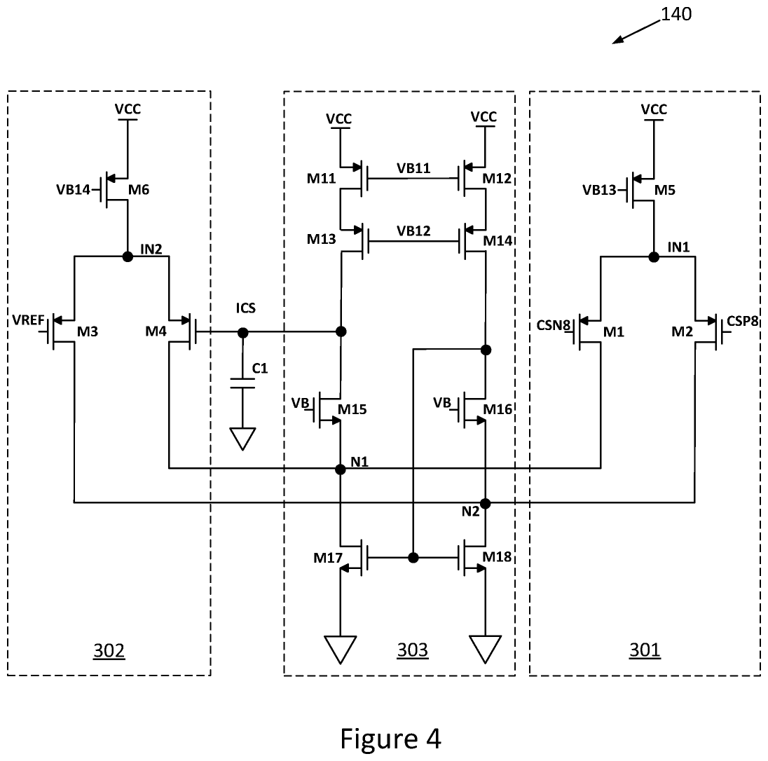

In operation, based on the current sense signals tapped at the CSP node and the CSN node, the current sensing apparatus 120 outputs current sensing signals CSN8 and CSP8. The current sensing signals CSN8 and CSP8 form a differential signal. The signal conversion apparatus 140 is configured to receive the differential signal, and convert this differential signal into a single-ended signal ICS. The value of the single-ended signal ICS includes two portions. A first portion is proportional to the current flowing through the current sense device RCS. The second portion is equal to a predetermined reference (not shown but illustrated in FIGS. 3-4). In other words, ICS is a level-shifted sensed current signal.

The PWM controller 110 is configured to receive a plurality of operating parameters including the sensed current signal ICS, a predetermined reference signal, an error amplifier output signal and the like. Based on the received signals, the PWM controller 110 is configured to generate gate drive voltages for switches Q1 and Q2.

In operation, the power converter 100 operates in a wide input voltage range. In some embodiments, the input voltage range is from 0 V to 60 V. The PWM controller 110 is able to generate a gate drive signal having a duty cycle up to 100%. As a result, the output voltage of the power converter 100 is in a range from 0 V to about 60 V.

It should be noted that the upper limit of the input voltage (e.g., 60 V) used in the previous example is selected purely for demonstration purposes and are not intended to limit the various embodiments of the present invention to any particular upper limit.

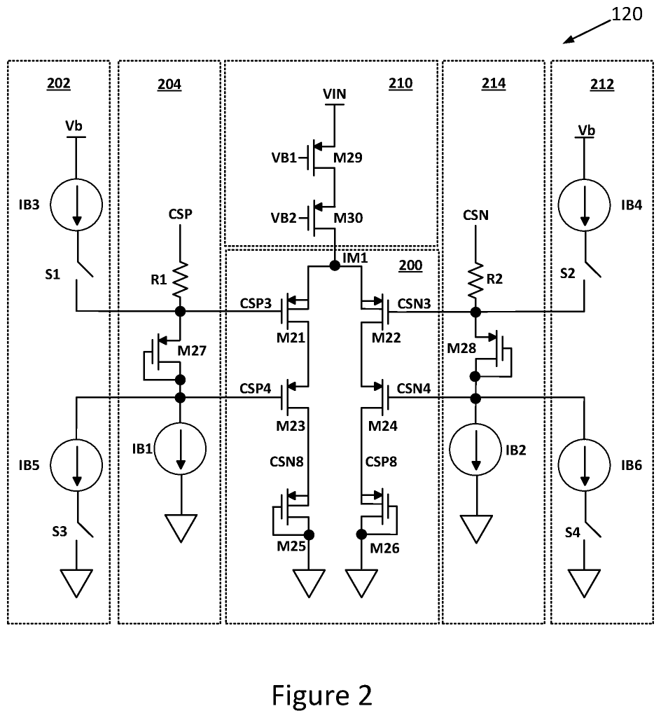

The current sensing apparatus 120 comprises a gain stage, a bias stage, a first track stage, a second track stage, a first auxiliary bias stage and a second auxiliary bias stage. In operation, the power converter 100 is configured to operate in an input voltage ranging from 0 V to 60 V. In response to this wide input voltage range, the current sensing apparatus 120 is configured to operate at a low voltage level (e.g., about 0 V) through enabling low voltage bias currents of the first auxiliary bias stage and the second auxiliary bias stage. The low voltage bias currents of the first auxiliary bias stage and the second auxiliary bias stage are able to establish adequate bias voltages for the gain stage. On the other hand, the current sensing apparatus 120 is configured to operate at a high voltage level (e.g., about 60 V) through enabling high voltage bias currents of the first auxiliary bias stage and the second auxiliary bias stage. The high voltage bias currents of the first auxiliary bias stage and the second auxiliary bias stage are able to establish adequate bias voltages for the gain stage. The operating principle of the current sensing apparatus 120 will be discussed in detail below with respect to FIG. 2.

The signal conversion apparatus 140 comprises a first differential pair, a second differential pair and a high gain stage. In operation, the signal conversion apparatus 140 is configured to receive the differential signal generated by the current sensing apparatus 120. As shown in FIG. 1, this differential signal is formed by the first current sensing signal CSN8 and the second current sensing signal CSP8. In operation, the signal conversion apparatus 140 is configured to convert the differential signal into a single-ended signal ICS through performing a dc detection on the differential signal, filtering noise components from the differential signal, and level-shifting the differential signal based on a predetermined reference. The operating principle of the signal conversion apparatus 140 will be discussed in detail below with respect to FIGS. 3-4.

FIG. 2 illustrates a schematic diagram of the current sensing apparatus shown in FIG. 1 in accordance with various embodiments of the present disclosure. The current sensing apparatus 120 comprises a gain stage 200, a bias stage 210, a first track stage 204, a second track stage 214, a first auxiliary stage 202 and a second auxiliary stage 212.

As shown in FIG. 2, the gain stage 200 comprises a first leg and a second leg. The first leg of the gain stage 200 comprises a first transistor M21, a third transistor M23 and a fifth transistor M25 connected in series between an intermediate node IM1 and ground. As shown in FIG. 2, a bulk terminal and a source of the first transistor M21 are connected together. A bulk terminal and a source of the fifth transistor M25 are connected together. A gate and a drain of the fifth transistor M25 are connected together. In operation, when the gain stage 200 undergoes amplification, the gain provided by the first transistor M21 is three times greater than the gain provided by the fifth transistor M25. The third transistor M23 functions as a buffer configured to provide high voltage isolation to protect the fifth transistor M25 from being damaged.

As shown in FIG. 2, the second leg of the gain stage 200 comprises a second transistor M22, a fourth transistor M24 and a sixth transistor M26 connected in series between the intermediate node IM1 and ground. As shown in FIG. 2, a bulk terminal and a source of the second transistor M22 are connected together. A bulk terminal and a source of the sixth transistor M26 are connected together. A gate and a drain of the sixth transistor M26 are connected together. In operation, when the gain stage 200 undergoes amplification, the gain provided by the second transistor M22 is three times greater than the gain provided by the sixth transistor M26. The fourth transistor M24 functions as a buffer configured to provide high voltage isolation to protect the sixth transistor M26 from being damaged.

The bias stage 210 comprises a ninth transistor M29 and the tenth transistor M30 connected in series between the input voltage VIN of the power converter 100 and the first intermediate node IM1. As shown in FIG. 2, the gate of M29 is connected to a first predetermined bias voltage VB1. The gate of M30 is connected to a second predetermined bias voltage VB2. The tenth transistor M30 is a high voltage transistor configured to provide isolation between the input voltage of the power converter, and the first current sensing node CSP and the second current sensing node CSN.

In some embodiments, transistors M21, M22, M25, M26 and M29 are low voltage switches. Transistors M23, M24 and M30 are high voltage switches. In some embodiments, the voltage rating of transistors M21, M22, M25, M26 and M29 is about 6 V. The voltage rating of transistors M23, M24 and M30 is about 60 V. The voltage rating of the high voltage switches (e.g., M30) is about ten times greater than that of the low voltage switches (e.g., M29).

In operation, the tenth transistor M30 is employed to provide isolation between the input voltage VIN of the power converter 100 and the CSP and CSN nodes. The third transistor M23 and the fourth transistor M24 are employed to provide isolation between high voltage nodes (e.g., CSP and CSN) and low voltage devices (e.g., M25 and M26).

The first track stage 204 comprises a first resistor R1, a seventh transistor M27 and a first current source IB1 connected in series between a first current sensing node CSP and ground. Referring back to FIG. 1, the CSP node is a common node of the inductor L1 and the current sense device RCS. As shown in FIG. 2, a common node of the first resistor R1 and the seventh transistor M27 is connected to a gate of the first transistor M21. The common node of the first resistor R1 and the seventh transistor M27 is denoted as CSP3 as shown in FIG. 2. A common node of the seventh transistor M27 and the first current source IB1 is connected to a gate of the third transistor M23. The common node of the seventh transistor M27 and the first current source IB1 is denoted as CSP4 as shown in FIG. 2. A drain and a gate of the seventh transistor M27 are connected together. In operation, the seventh transistor M27 functions as a first bias transistor configured to provide the operating headroom for the third transistor M23.

The second track stage 214 comprises a second resistor R2, an eighth transistor M28 and a second current source IB2 connected in series between a second current sensing node CSN and ground. Referring back to FIG. 1, the CSN node is a common node of the current sense device RCS and the output capacitor Co of the power converter 100. As shown in FIG. 2, a common node of the second resistor R2 and the eighth transistor M28 is connected to a gate of the second transistor M22. The common node of the second resistor R2 and the eighth transistor M28 is denoted as CSN3 as shown in FIG. 2. A common node of the eighth transistor M28 and the second current source IB2 is connected to a gate of the fourth transistor M24. The common node of the eighth transistor M28 and the second current source IB2 is denoted as CSN4 as shown in FIG. 2. A drain and a gate of the eighth transistor M28 are connected together. In operation, the eighth transistor M28 functions as a second bias transistor configured to provide the operating headroom for the fourth transistor M24.

In some embodiments, the current provided by the first current source IB1 is equal to the current provided by the second current source IB2. The current flowing through IB1 is about 1 microampere. R1 is a 10 k ohm resistor. R2 is a 10 k ohm resistor.

In operation, the current sensing apparatus 120 is able to operate in a wide range from a low voltage (e.g., 0 V) to a high voltage (e.g., 60 V). The current sensing apparatus 120 is dynamically biased by the voltages on the CSP and CSN nodes. The voltage on the CSP node provides the range of headroom available for M21. Likewise, voltage on the CSN node provides the range of headroom available for M22. The gate-to-source voltage of M27 provides the range of headroom available for M23, and gate-to-source voltage of M28 provides the range of headroom available for M24.

One advantageous feature of having M27 and M28 is that the current sensing accuracy can be significantly improved. In particular, the operating headroom for M23 and M24 is not related to the currents flowing through IB1 and IB2. As such, the currents flowing through IB1 and IB2 can be a small current such as 1 microampere. Under this small current, the voltages across R1 and R2 are about 10 millivolts. The semiconductor fabrication process may cause a 1% mismatch between the values of R1 and R2. The corresponding voltage mismatch is only about 0.1 millivolts. Such a small voltage mismatch provides an acceptable degree of current sensing accuracy. In some embodiments, by using M27 and M28, the current sensing accuracy error can be reduced from about 20% to about 3%.

In operation, when the current sensing apparatus 120 of the power converter 100 operates at a high voltage (e.g., about 60 V) or a low voltage (e.g., about 0 V), the first auxiliary bias stage 202 and the second auxiliary bias stage 212 are enabled to provide extra bias currents.

As shown in FIG. 2, the first auxiliary bias stage 202 comprises a low voltage bias current portion and a high voltage bias current portion. The low voltage bias current portion comprises a third current source IB3 and a first switch S1 connected in series between a bias voltage Vb and a gate of the first transistor M21. The high voltage bias current portion comprises a fifth current source IB5 and a third switch S3 connected in series between a gate of the third transistor M23 and ground. In some embodiments, the current flowing through the third current source IB3 is about 120 microamperes. The current flowing through the fifth current source IB5 is about 120 microamperes.

The second auxiliary bias stage 212 comprises a low voltage bias current portion and a high voltage bias current portion. The low voltage bias current portion comprises a fourth current source IB4 and a second switch S2 connected in series between the bias voltage Vb and a gate of the second transistor M22. The high voltage bias current portion comprises a sixth current source IB6 and a fourth switch S4 connected in series between a gate of the fourth transistor M24 and ground. In some embodiments, the current flowing through the fourth current source IB4 is about 120 microamperes. The current flowing through the sixth current source IB6 is about 120 microamperes.

In operation, in response to a voltage on the second current sensing node CSN approximately equal to a voltage on the ground rail (e.g., 0 V), the first switch S1 and the second switch S2 are configured to be turned on, and the third switch S3 and the fourth switch S4 are configured to be turned off. Once S1 is turned on, the current flowing through R1 establishes a bias voltage approximately equal to R1×IB3 (10K×120 uA), which is about 1.2 V. This bias voltage is able to provide enough operating headroom for the first transistor M21. Likewise, once S2 is turned on, the current flowing through R2 establishes a bias voltage approximately equal to R2×IB4 (10K×120 uA), which is about 1.2 V. This bias voltage is able to provide enough operating headroom for the second transistor M22.

In operation, in response to a voltage on the second current sensing node CSN approximately equal to a voltage on the power rail (e.g., 60 V), the first switch S1 and the second switch S2 are configured to be turned off, and the third switch S3 and the fourth switch S4 are configured to be turned on. Once S3 is turned on, the current flowing through R1 establishes a bias voltage approximately equal to R1×IB5 (10K×120 uA), which is about 1.2 V. This bias voltage is able to provide enough operating headroom for the first transistor M21. Likewise, once S4 is turned on, the current flowing through R2 establishes a bias voltage approximately equal to R2×IB6 (10K×120 uA), which is about 1.2 V. This bias voltage is able to provide enough operating headroom for the second transistor M22.

In operation, S1 and S2 may be controlled by a first comparator. The first comparator has a first input configured to receive a voltage signal proportional to the voltage on the second current sensing node CSN, a second input configured to receive a predetermined first voltage threshold approximately equal to a ground voltage potential (e.g., 0 V), and an output configured to generate a first control signal for controlling the first switch S1 and the second switch S2.

In operation, S3 and S4 may be controlled by a second comparator. The second comparator has a first input configured to receive the voltage signal proportional to the voltage on the second current sensing node CSN, a second input configured to receive a predetermined second voltage threshold approximately equal to an input voltage potential (e.g., 60 V), and an output configured to generate a second control signal for controlling the third switch S3 and the fourth switch S4.

FIG. 3 illustrates a block diagram of the signal conversion apparatus shown in FIG. 1 in accordance with various embodiments of the present disclosure. The signal conversion apparatus 140 comprises a first differential pair 301, a second differential pair 302, a high gain stage 303 and a capacitor C1. As shown in FIG. 3, the signal conversion apparatus 140 is configured to receive a differential signal formed by current sensing signals CSN8 and CSP8, and a predetermined reference VREF. Based on the received signals, the signal conversion apparatus 140 is configured to generate a single-ended signal ICS across the capacitor C1.

In some embodiments, the first differential pair 301 comprises a first transistor and a second transistor. A gate of the first transistor is configured to receive the first current sensing signal CSN8. A gate of the second transistor is configured to receive a second current sensing signal CSP8. A drain of the first transistor is connected to a first node N1 of the high gain stage 303. A drain of the second transistor is connected to a second node N2 of the high gain stage 303.

In some embodiments, the second differential pair 302 comprises a third transistor and a fourth transistor. A gate of the third transistor is configured to receive the predetermined reference VERF. A gate of the fourth transistor is connected to the capacitor C1. A drain of the third transistor is connected to the second node N2 of the high gain stage 303. A drain of the fourth transistor is connected to the first node N1 of the high gain stage 303.

In some embodiments, the high gain stage 303 comprises a first leg and a second leg. The first leg comprises four transistors connected in series between a bias voltage and ground. The second leg comprises four transistors connected in series between the bias voltage and ground.

In operation, the second differential pair 302, the capacitor C1 and the high gain stage 303 form a feedback loop to regulate a level-shifted voltage ICS across the capacitor C1. More particularly, through performing a de detection on the differential signal, filtering noise components from the differential signal, and level-shifting the differential signal based on the predetermined reference VREF, the level-shifted voltage ICS is generated across the capacitor C1. ICS is a single-ended signal.

In some embodiments, ICS can be expressed by the following equation:

$$ICS = VREF + K 1 \times ( CSP - CSN ) \qquad ( 1 )$$

In Equation (1), K1 is the current sense gain of the current sensing apparatus 120. The difference of CSP and CSN is equal to the voltage across the current sense device RCS, which is equal to the current flowing through RCS multiplied by the resistance of the current sense device RCS.

Referring back to FIG. 1, in some embodiments, the resistance of the current sense device RCS is 0.1 ohm. The current sense gain of the current sensing apparatus 120 is equal to three. The predetermined reference VREF is equal to 0.9 V. According to Equation (1), when the current flowing through RCS is equal to 4 amperes, ICS is equal to 2.1 V. When the current flowing through RCS is equal to 2 amperes, ICS is equal to 1.5 V. When the current flowing through RCS is equal to −1 ampere, ICS is equal to 0.6 V. In a wide load range from −1 A to 4 A, the signal conversion apparatus 140 is able to generate a single-ended signal having a voltage range (from 0.6 V to 2.1 V) suitable for subsequent signal processing (e.g., A/D conversion).

FIG. 4 illustrates a schematic diagram of the signal conversion apparatus shown in FIG. 3 in accordance with various embodiments of the present disclosure. The signal conversion apparatus 140 comprises a first differential pair 301, a second differential pair 302, a high gain stage 303 and a capacitor C1. The capacitor C1 is coupled between the second differential pair 302 and the high gain stage 303.

The first differential pair 301 comprises a fifth transistor M5, a first transistor M1 and a second transistor M2. The fifth transistor M5 is connected between a bias voltage VCC and a first internal node IN1. The first transistor M1 is connected between the first internal node IN1 and a first node N1 of a first leg of the high gain stage 303. The second transistor M2 is connected between the first internal node IN1 and a second node N2 of a second leg of the high gain stage 303.

As shown in FIG. 4, the first transistor M1, the second transistor M2 and the fifth transistor M5 are p-type transistors. A source of the fifth transistor M5 is connected to the bias voltage VCC. A drain of the fifth transistor M5 is connected to the first internal node IN1. A gate of the fifth transistor M5 is connected to a bias voltage VB13. A source of the first transistor M1 is connected to the first internal node IN1. A drain of the first transistor M1 is connected to the first node N1 of the first leg of the high gain stage 303. A gate of the first transistor M1 is configured to receive the first current sensing signal CSN8. A source of the second transistor M2 is connected to the first internal node IN1. A drain of the second transistor M2 is connected to the second node N2 of the second leg of the high gain stage 303. A gate of the second transistor M2 is configured to receive the second current sensing signal CSP8.

The second differential pair 302 comprises a sixth transistor M6, a third transistor M3 and a fourth transistor M4. The sixth transistor M6 is connected between the bias voltage VCC and a second internal node IN2. The third transistor M3 is connected between the second internal node IN2 and the second node N2 of the second leg of the high gain stage 303. The fourth transistor M4 is connected between the second internal node IN2 and the first node N1 of the first leg of the high gain stage 303.

As shown in FIG. 4, the third transistor M3, the fourth transistor M4 and the sixth transistor M6 are p-type transistors. A source of the sixth transistor M6 is connected to the bias voltage VCC. A drain of the sixth transistor M6 is connected to the second internal node IN2. A gate of the sixth transistor M6 is connected to a bias voltage VB14. A source of the third transistor M3 is connected to the second internal node IN2. A drain of the third transistor M3 is connected to the second node N2 of the second leg of the high gain stage 303. A gate of the third transistor M3 is configured to receive the predetermined reference VREF. A source of the fourth transistor M4 is connected to the second internal node IN2. A drain of the fourth transistor M4 is connected to the first node N1 of the first leg of the high gain stage 303. A gate of the fourth transistor M4 is connected to a first terminal of the capacitor C1. A second terminal of the capacitor C1 is connected to ground.

As shown in FIG. 4, the first leg of the high gain stage 303 comprises a first high gain stage transistor M11, a third high gain stage transistor M13, a fifth high gain stage transistor M15 and a seventh high gain stage transistor M17 connected in series between the bias voltage VCC and ground. The second leg of the high gain stage 303 comprises a second high gain stage transistor M12, a fourth high gain stage transistor M14, a sixth high gain stage transistor M16 and an eighth high gain stage transistor M16 connected in series between the bias voltage VCC and ground.

As shown in FIG. 4, the first high gain stage transistor M11, the second high gain stage transistor M12, the third high gain stage transistor M13 and the fourth high gain stage transistor M14 are p-type transistors. The fifth high gain stage transistor M15, the sixth high gain stage transistor M16, the seventh high gain stage transistor M17 and the eighth high gain stage transistor M18 are n-type transistors. The gates of M11 and M12 are connected to a bias voltage VB11. The gates of M13 and M14 are connected to a bias voltage VB12. The gates of M15 and M16 are connected to a bias voltage VB. The gates of M17 and M18 are connected together and further connected to a common node of M14 and M16.

As shown in FIG. 4, a common node of the fifth high gain stage transistor M15 and the seventh high gain stage transistor M17 is the first node N1 of the first leg of the high gain stage 303. A common node of the sixth high gain stage transistor M16 and the eighth high gain stage transistor M18 is the second node N2 of the second leg of the high gain stage 303. A common node of the third high gain stage transistor M13 and the fifth high gain stage transistor M15 is connected to the capacitor C1.

In operation, the first differential pair 301 is configured to receive the current sensing signals CSN8 and CSP8 generated by the current sensing apparatus 120. The current sensing signals CSN8 and CSP8 form a differential signal. The second differential pair 302, the capacitor C1 and the high gain stage 303 form a feedback loop to regulate a level-shifted voltage ICS across the capacitor C1. More particularly, the capacitor C1 is employed to filter the noise components from the differential signal formed by CSN8 and CSP8. The second differential pair 302 and the high gain stage 303 level-shift the differential signal based on the predetermined reference VREF, and generate the level-shifted voltage ICS across the capacitor C1. The level-shifted voltage ICS is a single-ended signal. In some embodiments, ICS is a sum of the predetermined reference VREF and a voltage signal proportional to the current flowing through the current sense device RCS.

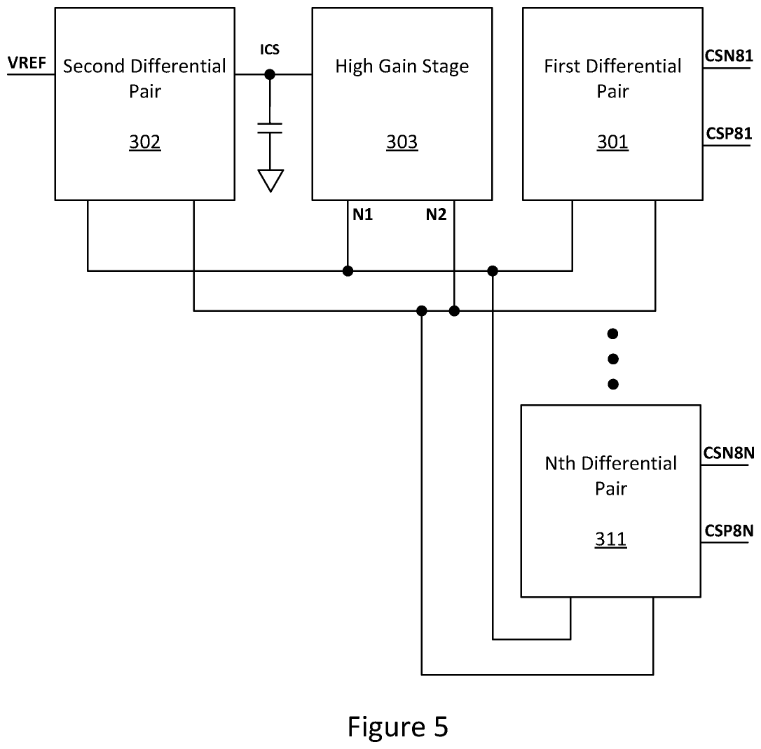

FIG. 5 illustrates a block diagram of another signal conversion apparatus in accordance with various embodiments of the present disclosure. The signal conversion apparatus shown in FIG. 5 is similar to the signal conversion apparatus shown in FIG. 3 except that a plurality of differential pairs is coupled to the first node N1 and the second node N2 of the high gain stage 303.

As shown in FIG. 5, a plurality of differential pairs (e.g., nth differential pair 311) is coupled to the high gain stage 303. Each of the plurality of differential pairs comprises a first input, a second input, a first output and a second output. The first input and the second input are configured to receive a differential signal formed by current sensing signals (e.g., differential signal formed by current sensing signals CSN8N and CSP8N). The first output is connected to the first node N1 of the first leg of the high gain stage 303. The second output is connected to the second node N2 of the second leg of the high gain stage 303. The plurality of differential pairs (e.g., differential pairs 301 and 311) are configured to receive current sensing signals representing the currents flowing through a plurality of power converters.

In operation, the second differential pair 302, the capacitor C1 and the high gain stage 303 form a feedback loop to regulate a voltage ICS across the capacitor C1. More particularly, through performing a de detection on the differential signal, filtering noise components from the differential signal, and level-shifting the differential signals based on the predetermined reference VREF, the voltage ICS is generated across the capacitor C1. ICS is a single-ended signal.

In some embodiments, ICS can be expressed by the following equation:

ICS=VREF+Σᵢ₌₁ⁿKi×(CSPi−CSNi) (2)

In Equation (2), Ki is the current sense gain of a corresponding current sensing apparatus. For example, the current sense gain of the current sensing apparatus 120 is equal to three. The difference of CSPi and CSNi is the voltage across a corresponding current sense device RCS, which is equal to the current flowing through RCS multiplied by the resistance of RCS.

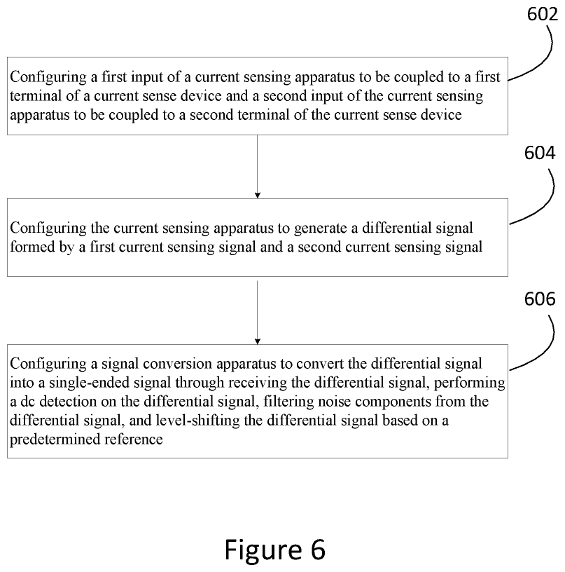

FIG. 6 illustrates a flow chart of controlling and operating the signal conversion apparatus shown in FIG. 1 in accordance with various embodiments of the present disclosure. This flowchart shown in FIG. 6 is merely an example, which should not unduly limit the scope of the claims. One of ordinary skill in the art would recognize many variations, alternatives, and modifications. For example, various steps illustrated in FIG. 6 may be added, removed, replaced, rearranged and repeated.

Referring back to FIG. 1, a current sensing apparatus (e.g., current sensing apparatus 120) is configured to receive detected voltages on the CSP and CSN nodes. The current sensing apparatus is configured to generate current sensing signals (e.g., CSP8 and CSN8) based on the detected voltages. The current sensing signals form a differential signal. This differential signal is fed into a signal conversion apparatus (e.g., signal conversion apparatus 140) where the differential signal is converted into a single-ended signal (e.g., ICS). The single-ended signal and other operating parameters are fed into a PWM controller where gate drive signals are generated to control the on and off of the power switches (e.g., Q1 and Q2).

Referring back to FIGS. 3-4, the signal conversion apparatus comprises a first differential pair, a second differential pair, a high gain stage and a capacitor. The first differential pair is configured to receive the current sensing signals CSP8 and CSN8. The second differential pair is configured to receive a predetermined reference VREF. The signal conversion apparatus converts a differential signal formed by CSP8 and CSN8 into a single-ended signal having a suitable voltage range for subsequent signal processing.

At step 602, a first input of a current sensing apparatus is configured to be coupled to a first terminal of a current sense device and a second input of the current sensing apparatus is configured to be coupled to a second terminal of the current sense device.

At step 604, the current sensing apparatus is configured to generate a differential signal formed by a first current sensing signal and a second current sensing signal.

At step 606, a signal conversion apparatus is configured to convert the differential signal into a single-ended signal through receiving the differential signal, performing a de detection on the differential signal, filtering noise components from the differential signal, and level-shifting the differential signal based on a predetermined reference.

Referring back to FIG. 4, the signal conversion apparatus comprises a high gain stage comprising a first leg and a second leg, and wherein the first leg of the high gain stage comprises a first high gain stage transistor, a third high gain stage transistor, a fifth high gain stage transistor and a seventh high gain stage transistor connected in series between a bias voltage and ground, and the second leg of the high gain stage comprises a second high gain stage transistor, a fourth high gain stage transistor, a sixth high gain stage transistor and an eighth high gain stage transistor connected in series between a bias voltage and ground. The signal conversion apparatus further comprises a first differential pair comprising a fifth transistor, a first transistor and a second transistor, and wherein the fifth transistor is connected between a bias voltage and a first internal node, the first transistor is connected between the first internal node, and a common node of the fifth high gain stage transistor and the seventh high gain stage transistor, and the second transistor is connected between the first internal node and a common node of the sixth high gain stage transistor and the eighth high gain stage transistor. The signal conversion apparatus further comprises a second differential pair comprising a sixth transistor, a third transistor and a fourth transistor, and wherein the sixth transistor is connected between the bias voltage and a second internal node, the third transistor is connected between the second internal node and the common node of the sixth high gain stage transistor and the eighth high gain stage transistor, and the fourth transistor is connected between the second internal node and the common node of the fifth high gain stage transistor and the seventh high gain stage transistor.

Referring back to FIG. 1, the current sense device is a current sense resistor of a power converter.

Referring back to FIG. 1, the power converter comprises a first power switch and a second power switch connected in series between an input voltage bus and ground, an inductor connected between a common node of the first power switch and the second power switch and a first terminal of the current sense device, and an output capacitor connected between a second terminal of the current sense device and ground.

Although embodiments of the present disclosure and its advantages have been described in detail, it should be understood that various changes, substitutions and alterations can be made herein without departing from the spirit and scope of the disclosure as defined by the appended claims.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. An apparatus comprising:
a first differential pair having a first transistor and a second transistor, wherein a gate of the first transistor is configured to receive a first current sensing signal, and a gate of the second transistor is configured to receive a second current sensing signal;
a second differential pair having a third transistor and a fourth transistor, wherein a gate of the third transistor is configured to receive a predetermined reference, and a gate of the fourth transistor is connected to a capacitor; and
a high gain stage comprising a first leg and a second leg, wherein a first node of the first leg is connected to a drain of the first transistor and a drain of the fourth transistor, and a second node of the second leg is connected to a drain of the second transistor and a drain of the third transistor, and wherein the high gain stage is configured to regulate a voltage across the capacitor.

2. The apparatus of claim 1, wherein:
the first differential pair comprises a fifth transistor, the first transistor and the second transistor, and wherein:
the fifth transistor is connected between a bias voltage and a first internal node;
the first transistor is connected between the first internal node and the first node of the first leg of the high gain stage; and
the second transistor is connected between the first internal node and the second node of the second leg of the high gain stage.

3. The apparatus of claim 2, wherein:
the first transistor, the second transistor and the fifth transistor are p-type transistors;
a source of the fifth transistor is connected to the bias voltage;
a drain of the fifth transistor is connected to the first internal node;
a source of the first transistor is connected to the first internal node;
a drain of the first transistor is connected to the first node of the first leg of the high gain stage;
a source of the second transistor is connected to the first internal node; and
a drain of the second transistor is connected to the second node of the second leg of the high gain stage.

4. The apparatus of claim 1, wherein:
the second differential pair comprises a sixth transistor, the third transistor and the fourth transistor, and wherein:
the sixth transistor is connected between a bias voltage and a second internal node;
the third transistor is connected between the second internal node and the second node of the second leg of the high gain stage; and
the fourth transistor is connected between the second internal node and the first node of the first leg of the high gain stage.

5. The apparatus of claim 4, wherein:
the third transistor, the fourth transistor and the sixth transistor are p-type transistors;
a source of the sixth transistor is connected to the bias voltage;
a drain of the sixth transistor is connected to the second internal node;
a source of the third transistor is connected to the second internal node;
a drain of the third transistor is connected to the second node of the second leg of the high gain stage;
a source of the fourth transistor is connected to the second internal node; and
a drain of the fourth transistor is connected to the first node of the first leg of the high gain stage.

6. The apparatus of claim 1, wherein:
the first leg of the high gain stage comprises a first high gain stage transistor, a third high gain stage transistor, a fifth high gain stage transistor and a seventh high gain stage transistor connected in series between a bias voltage and ground; and
the second leg of the high gain stage comprises a second high gain stage transistor, a fourth high gain stage transistor, a sixth high gain stage transistor and an eighth high gain stage transistor connected in series between a bias voltage and ground.

7. The apparatus of claim 6, wherein:
a common node of the fifth high gain stage transistor and the seventh high gain stage transistor is the first node of the first leg of the high gain stage;
a common node of the sixth high gain stage transistor and the eighth high gain stage transistor is the second node of the second leg of the high gain stage; and
a common node of the third high gain stage transistor and the fifth high gain stage transistor is connected to the capacitor; and
a common node of the fourth high gain stage transistor and the sixth high gain stage transistor is connected to a gate of the seventh high gain stage transistor and a gate of the eighth high gain stage transistor.

8. The apparatus of claim 6, wherein:
the first high gain stage transistor, the second high gain stage transistor, the third high gain stage transistor and the fourth high gain stage transistor are p-type transistors; and
the fifth high gain stage transistor, the sixth high gain stage transistor, the seventh high gain stage transistor and the eighth high gain stage transistor are n-type transistors.

9. The apparatus of claim 1, further comprising:
a plurality of differential pairs coupled to the high gain stage, wherein each of the plurality of differential pairs comprises:
a first input and a second input configured to receive a current sense differential signal;
a first output connected to the first node of the first leg of the high gain stage;
a second output connected to the second node of the second leg of the high gain stage.

10. The apparatus of claim 9, wherein:
the first differential pair and the plurality of differential pairs are configured to receive sensed currents flowing through a plurality of power converters.

11. The apparatus of claim 1, wherein:
the first current sensing signal and the second current sensing signal form a differential signal, and wherein the first differential pair, the second differential pair and the high gain stage are configured to convert the differential signal into a regulated single-ended signal across the capacitor.

12. The apparatus of claim 1, wherein:
the first current sensing signal and the second current sensing signal are generated by a current sensing apparatus of a power converter, and wherein the power converter comprises:
a first power switch and a second power switch connected in series between an input voltage bus and ground;
an inductor connected between a common node of the first power switch and the second power switch, and a first terminal of the current sense device;
an output capacitor connected between a second terminal of the current sense device and ground.

13. The apparatus of claim 12, wherein the current sensing apparatus comprises:
a gain stage comprising:
a first current sense transistor, a third current sense transistor and a fifth current sense transistor connected in series between an intermediate node and ground, and wherein the first current sensing signal is generated at a common node of the third current sense transistor and the fifth current sense transistor; and
a second current sense transistor, a fourth current sense transistor and a sixth current sense transistor connected in series between the intermediate node and ground, and wherein the second current sensing signal is generated at a common node of the fourth current sense transistor and the sixth current sense transistor;
a first track stage comprising a first resistor, a seventh current sense transistor and a first current source connected in series between the first terminal of the current sense device and ground, and wherein a common node of the first resistor and the seventh current sense transistor is connected to a gate of the first current sense transistor, and a common node of the seventh current sense transistor and the first current source is connected to a gate of the third current sense transistor;
a second track stage comprising a second resistor, an eighth current sense transistor and a second current source connected in series between the second terminal of the current sense device and ground, and wherein a common node of the second resistor and the eighth current sense transistor is connected to a gate of the second current sense transistor, and a common node of the eighth current sense transistor and the second current source is connected to a gate of the fourth current sense transistor;
a bias stage comprising a ninth current sense transistor and a tenth current sense transistor connected in series between an input voltage of the power converter and the intermediate node;
a first auxiliary bias stage comprising:
a third current source and a first switch connected in series between a bias voltage and the gate of the first current sense transistor; and
a third switch and a fifth current source connected in series between the gate of the third current sense transistor and ground; and
a second auxiliary bias stage comprising:
a fourth current source and a second switch connected in series between the bias voltage and the gate of the second current sense transistor; and
a fourth switch and a sixth current source connected in series between the gate of the fourth current sense transistor and ground.

14. A method comprising:
configuring a first input of a current sensing apparatus to be coupled to a first terminal of a current sense device and a second input of the current sensing apparatus to be coupled to a second terminal of the current sense device;
configuring the current sensing apparatus to generate a differential signal formed by a first current sensing signal and a second current sensing signal; and
configuring a signal conversion apparatus to convert the differential signal into a single-ended signal through receiving the differential signal, performing a dc detection on the differential signal, filtering noise components from the differential signal, and level-shifting the differential signal based on a predetermined reference.

15. The method of claim 14, wherein the signal conversion apparatus comprises:
a high gain stage comprising a first leg and a second leg, and wherein:
the first leg of the high gain stage comprises a first high gain stage transistor, a third high gain stage transistor, a fifth high gain stage transistor and a seventh high gain stage transistor connected in series between a bias voltage and ground; and
the second leg of the high gain stage comprises a second high gain stage transistor, a fourth high gain stage transistor, a sixth high gain stage transistor and an eighth high gain stage transistor connected in series between a bias voltage and ground;
a first differential pair comprising a fifth transistor, a first transistor and a second transistor, and wherein:
the fifth transistor is connected between a bias voltage and a first internal node;
the first transistor is connected between the first internal node, and a common node of the fifth high gain stage transistor and the seventh high gain stage transistor; and
the second transistor is connected between the first internal node and a common node of the sixth high gain stage transistor and the eighth high gain stage transistor; and
a second differential pair comprising a sixth transistor, a third transistor and a fourth transistor, and wherein:
the sixth transistor is connected between the bias voltage and a second internal node;
the third transistor is connected between the second internal node and the common node of the sixth high gain stage transistor and the eighth high gain stage transistor; and
the fourth transistor is connected between the second internal node and the common node of the fifth high gain stage transistor and the seventh high gain stage transistor.

16. The method of claim 14, wherein:
the current sense device is a current sense resistor of a power converter.

17. The method of claim 16, wherein the power converter comprises:
a first power switch and a second power switch connected in series between an input voltage bus and ground;
an inductor connected between a common node of the first power switch and the second power switch and a first terminal of the current sense device; and
an output capacitor connected between a second terminal of the current sense device and ground.

18. A power converter comprising:
a first power switch and a second power switch connected in series between an input voltage bus and ground;
an inductor connected between a common node of the first power switch and the second power switch and a first terminal of a current sense device;
a capacitor connected between a second terminal of the current sense device and ground;
a current sensing apparatus having a first input connected to the first terminal of the current sense device and a second input connected to the second terminal of the current sense device, wherein the current sensing apparatus is configured to generate a differential signal formed by a first current sensing signal and a second current sensing signal; and
a signal conversion apparatus configured to convert the differential signal into a single-ended signal across a capacitor through receiving the differential signal, performing a dc detection on the differential signal, filtering noise components from the differential signal, and level-shifting the differential signal based on a predetermined reference.

19. The power converter of claim 18, wherein the signal conversion apparatus comprises:
a first differential pair having a first transistor and a second transistor, and wherein a gate of the first transistor is configured to receive the first current sensing signal, and a gate of the second transistor is configured to receive the second current sensing signal;
a second differential pair having a third transistor and a fourth transistor, wherein a gate of the third transistor is configured to receive the predetermined reference, and a gate of the fourth transistor is connected to the capacitor; and
a high gain stage comprising a first leg and a second leg, and wherein a first node of the first leg is connected to a drain of the first transistor and a drain of the fourth transistor, and a second node of the second leg is connected to a drain of the second transistor and a drain of the third transistor, and wherein the high gain stage is configured to regulate a voltage across the capacitor.

20. The power converter of claim 19, wherein:
the first leg of the high gain stage comprises a first high gain stage transistor, a third high gain stage transistor, a fifth high gain stage transistor and a seventh high gain stage transistor connected in series between a bias voltage and ground;
the second leg of the high gain stage comprises a second high gain stage transistor, a fourth high gain stage transistor, a sixth high gain stage transistor and an eighth high gain stage transistor connected in series between a bias voltage and ground;
the first differential pair comprises a fifth transistor, the first transistor and the second transistor, and wherein:
the fifth transistor is connected between the bias voltage and a first internal node;
the first transistor is connected between the first internal node, and a common node of the fifth high gain stage transistor and the seventh high gain stage transistor; and
the second transistor is connected between the first internal node and a common node of the sixth high gain stage transistor and the eighth high gain stage transistor; and
the second differential pair comprises a sixth transistor, the third transistor and the fourth transistor, and wherein:
the sixth transistor is connected between the bias voltage and a second internal node;
the third transistor is connected between the second internal node and the common node of the sixth high gain stage transistor and the eighth high gain stage transistor; and
the fourth transistor is connected between the second internal node and the common node of the fifth high gain stage transistor and the seventh high gain stage transistor.
